(19) United States
(12) Patent Application Publication
(10) Pub. No.: US 2025/0257454 A1
(43) Pub. Date: Aug. 14, 2025

(54) SIDE BLOCKS FOR GAS ACTIVATION, AND RELATED PROCESSING CHAMBERS, PROCESS KITS, AND METHODS

(71) Applicant: Applied Materials, Inc., Santa Clara, CA (US)

(72) Inventor: Zhepeng CONG, San Jose, CA (US)

(21) Appl. No.: 18/619,752

(22) Filed: Mar. 28, 2024

Related U.S. Application Data
(60) Provisional application No. 63/553,513, filed on Feb. 14, 2024.

(51) Int. Cl. C23C 16/455; C23C 16/32

(52) U.S. Cl. CPC C23C 16/45525; C23C 16/325

(57) ABSTRACT

Embodiments of the present invention relate to blocks for gas activation, related substrate processing chambers, process kits, and methods. In some embodiments, a processing chamber applicable for use in semiconductor manufacturing includes a chamber body at least partially defining an internal volume, one or more heat sources operable to heat the internal volume, and a substrate support disposed in the internal volume. The processing chamber further includes one or more inlet openings configured to direct a gas across a gas flow path over the substrate support and to one or more exhaust outlets and a process kit disposed in the internal volume. The process kit includes a first flow guide block and a second flow guide block disposed opposite the first flow guide block with respect to the gas flow path. The first flow guide block and the second flow guide block respectively include one or more opaque outer surfaces.

### CROSS-REFERENCE TO RELATED APPLICATION

This application claims priority to U.S. provisional patent application Ser. No. 63/553,513, filed Feb. 14, 2024, which is herein incorporated by reference in its entirety.

### BACKGROUND

### Field

Embodiments of the present invention generally relate to blocks for gas activation, and related substrate processing chambers, process kits, and methods.

### Description of the Related Art

Semiconductor substrates are processed for a wide variety of applications, including the fabrication of integrated devices and microdevices. During processing, various parameters can affect the uniformity of material deposited on the substrate. For example, the temperature of the substrate and/or temperature(s) of processing chamber component(s) can affect deposition uniformity.

It can be difficult to adjust parameters (such as gas flow rates and gas pressures) for deposition uniformity. Rotation of the substrate, if used, can exacerbate adjustment difficulties. Relatively low rotation speeds, high pressures, and low flow rates can also exacerbate adjustment difficulties. Moreover, it can be difficult to clean components of processing chambers. Additionally, it can be difficult to activate processing gases. The activation of processing gases can be non-uniform, which can cause non-uniform processing.

Therefore, a need exists for improved process kits and related methods and processing chambers.

### SUMMARY

Embodiments of the present invention generally relate to blocks for gas activation, and related substrate processing chambers, process kits, and methods.

In one or more embodiments, a processing chamber applicable for use in semiconductor manufacturing includes a chamber body at least partially defining an internal volume, one or more heat sources operable to heat the internal volume, and a substrate support disposed in the internal volume. The processing chamber further includes one or more inlet openings configured to direct a gas across a gas flow path over the substrate support and to one or more exhaust outlets and a process kit disposed in the internal volume. The process kit includes a first flow guide block and a second flow guide block disposed opposite the first flow guide block with respect to the gas flow path. The first flow guide block and the second flow guide block respectively include one or more opaque outer surfaces.

In one or more embodiments, a process kit applicable for use in semiconductor manufacturing includes a plate, a first block operable to support at least a first portion of the plate, and a second block operable to support at least a second portion of the plate. The first block and the second block respectively include one or more opaque outer surfaces.

In one or more embodiments, a method of processing substrates includes heating a substrate positioned on a substrate support and flowing one or more process gases over the substrate to form one or more layers on the substrate. The flowing of the one or more process gases over the substrate includes flowing the one or more process gases over a pair of blocks having opaque surfaces defining a rectangular flow opening.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a partial schematic side cross-sectional view of a processing chamber, according to one or more embodiments.

FIG. 2 is a partial schematic side cross-sectional view of a processing chamber, according to one or more embodiments.

FIG. 3 is a schematic partial perspective view of the process kit according to one or more embodiments.

FIG. 4 is a partial schematic side cross-sectional view of an isolation plate within a processing chamber, according to one or more embodiments.

FIG. 5 is a schematic partial perspective view of a process kit, according to one or more embodiments.

FIG. 6 is a schematic block diagram view of a method of processing substrates, according to one or more embodiments.

FIGS. 7A-7C are schematic partial perspective views of elements of a process kit, according to one or more embodiments.

FIG. 8A is schematic cross-sectional top view of a processing chamber, according to one or more embodiments.

FIG. 8B is schematic cross-sectional side view of a processing chamber, according to one or more embodiments.

FIG. 8C is schematic cross-sectional top view of the processing chamber shown in FIG. 8B, according to one or more embodiments.

FIG. 9A is a graphical representation of the deposition rate on a substrate during an epitaxial deposition process using various implementations, according to one or more embodiments.

FIG. 9B is a graphical representation of the phosphorous content on a substrate during an epitaxial deposition process using various implementations, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to a semiconductor processing chamber, and more particularly, to one or more methods of apparatuses for introducing purge gas within a processing chamber.

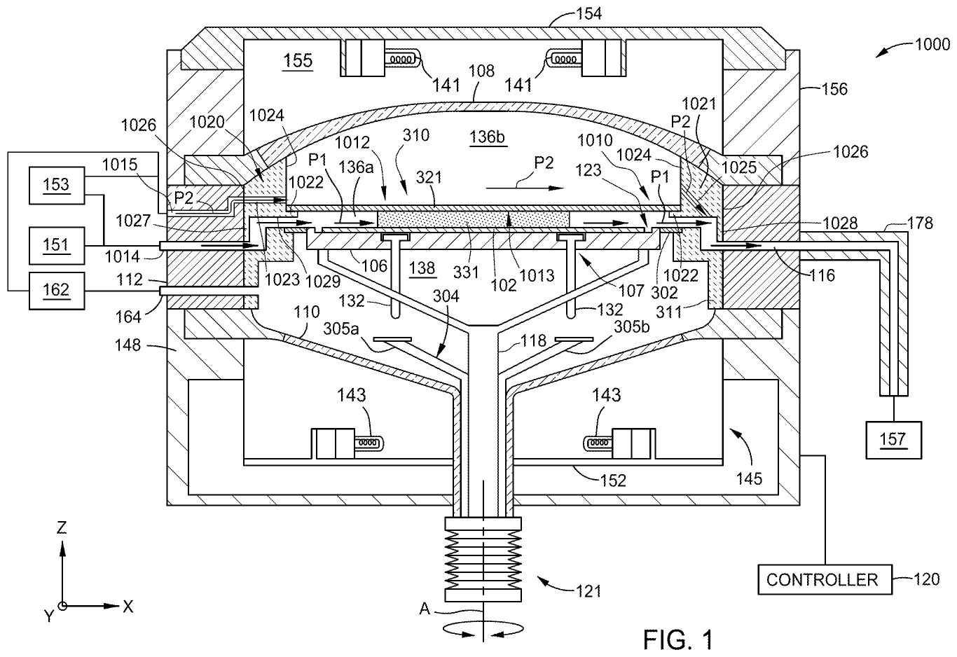

FIG. 1 is a partial schematic side cross-sectional view of a processing chamber 1000, according to one or more embodiments. The processing chamber 1000 is a deposition chamber. In one or more embodiments, the processing chamber 1000 is an epitaxial deposition chamber. The processing chamber 1000 is utilized to grow an epitaxial film on a substrate 102. The processing chamber 1000 creates a cross-flow of precursors across a top surface of the substrate 102. The processing chamber 1000 is shown in a processing condition in FIG. 1.

The processing chamber 1000 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), a plurality of upper heat sources 141, and a plurality of lower heat sources 143. As shown, a controller 120 is in communication with the processing chamber 100 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used.

The substrate support 106 is disposed between the upper window 108 and the lower window 110. The substrate support 106 includes a support face 123 that supports the substrate 102. The plurality of upper heat sources 141 are disposed between the upper window and a lid 154. The plurality of upper heat sources 141 form a portion of the upper heat source module 155. The lid 154 may include a plurality of sensors disposed therein or thereon for measuring the temperature within the processing chamber 100. The plurality of lower heat sources 143 are disposed between the lower window 110 and a floor 152. The plurality of lower heat sources 143 form a portion of a lower heat source module 145. In one or more embodiments, the upper window 108 is an upper dome and is formed of an energy transmissive material, such as quartz. In one or more embodiments, the lower window 110 is a lower dome and is formed of an energy transmissive material, such as quartz. A pre-heat ring 302 is disposed outwardly of the substrate support 106. The pre-heat ring 302 is supported on a ledge of the lower liner 311. A stop 304 includes a plurality of arms 305a, 305b that each include a lift pin stop on which at least one of the lift pins 132 can rest when the substrate support 106 is lowered (e.g., lowered from a process position to a transfer position).

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106.

The substrate support 106 may include lift pin perforations 107 disposed therein. The lift pin perforations 107 are sized to accommodate a lift pin 132 for lifting of the substrate 102 from the substrate support 106 either before or after a deposition process is performed.

A process kit 1010 includes an isolation plate 321 having a first face 1012 and a second face 1013 opposing the first face 1012. The second face 1013 faces the substrate support 106. The process kit 1010 includes an upper liner 1020. The upper liner 1020 includes an annular section 1021. The upper liner 1020 includes one or more inlet openings 1023 extending to an inner surface 1024 of the annular section 1021 on a first side of the upper liner 1020, and one or more outlet openings 1025 extending to the inner surface 1024 of the annular section 1021 on a second side of the upper liner 1020.

The one or more inlet openings 1023 extend from an outer surface 1026 of the annular section 1021 of the upper liner 1020 to the inner surface 1024. The one or more outlet openings 1025 extend from a lower surface 1029 of the upper liner 1020 to the inner surface 1024. The upper liner 1020 includes a first extension 1027 and a second extension 1028 disposed outwardly of the lower surface 1029 of the upper liner 1020. At least part of the annular section 1021 of the upper liner 1020 is aligned with the first extension 1027 and the second extension 1028. In the embodiment shown in FIG. 1, a lowermost end of the isolation plate 321 is aligned above a lowermost end of the upper liner 1020. In one or more embodiments, as shown in FIG. 1, the lowermost end of the isolation plate 321 is part of the second face 1013, and the lowermost end of the upper liner 1020 is part of the first extension 1027 and/or the second extension 1028. The present disclosure contemplates that the lowermost end of the upper liner 1020 can be part of the lower surface 1029.

The isolation plate 321 is in the shape of a disc, and the annular section 1021 is in the shape of a ring. It is contemplated, however, that the isolation plate 321 and/or the annular section 1021 can be in the shape of a rectangle, or other geometric shapes. The isolation plate 321 at least partially fluidly isolates the upper portion 136b from the lower portion 136a. The lower portion 136a has a smaller volume than the upper portion 136b. A ratio of the volume of the lower portion 136a relative to the volume of the upper portion 136b is less than 0.25.

The flow module 112 (which can define at least part of one or more sidewalls of the processing chamber 1000) includes one or more first inlet openings 1014 in fluid communication with the lower portion 136a of the processing volume 136. The flow module 112 includes one or more second inlet openings 1015 in fluid communication with the upper portion 136b of the processing volume 136. The one or more first inlet openings 1014 are in fluid communication with one or more flow gaps between the upper liner 1020 and the lower liner 311. The one or more second inlet openings 1015 are in fluid communication with the one or more inlet openings 1023 of the upper liner 1020. The one or more inlet openings 1014 are fluidly connected to one or more process gas sources 151 and one or more cleaning gas sources 153. The purge gas inlet(s) 164 are fluidly connected to one or more purge gas sources 162. The one or more exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen and/or chlorine. In one or more embodiments, the one or more process gases include silicon phosphide (SiP) and/or phospine (PH₃), and the one or more cleaning gases include hydrochloric acid (HCl).

The one or more exhaust outlets 116 are further connected to or include an exhaust system 178. The exhaust system 178 fluidly connects the one or more exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112. The one or more inlet openings 114 are configured to direct a gas (such as the process gas(es) P1) across a gas flow path over the substrate support 106 and to the one or more exhaust outlets 116.

In one or more embodiments, as shown in FIG. 1, the one or more inlet openings 1023 are oriented in a horizontal orientation and the one or more outlet openings 1025 are oriented in an angled orientation. The present disclosure contemplates that the one or more inlet and/or outlet openings 1023, 1025 can be oriented in a horizontal orientation, oriented in an angled (e.g., non-parallel to horizontal) orientation, and/or can include one or more turns (such as the turns shown for the one or more first inlet openings 1014 and the one or more exhaust outlets 116).

During a deposition operation (e.g., an epitaxial growth operation), the one or more process gases P1 flow through the one or more first inlet openings 1014, through the one or more gaps, and into the lower portion 136a of the processing volume 136 to flow across a gas flow path over the substrate 102. During the deposition operation, one or more purge gases P2 flow through the one or more second inlet openings 1015, through the one or more inlet openings 1023 of the upper liner 1020, and into the upper portion 136b of the processing volume 136. The one or more purge gases P2 flow simultaneously with the flowing of the one or more process gases P1. The flowing of the one or more purge gases P2 through the upper portion 136b facilitates reducing or preventing flow of the one or more process gases P1 into the upper portion 136b that would contaminate the upper portion 136b. The one or more process gases P1 are exhausted through gaps between the upper liner 1020 and the lower liner 311, and through the one or more exhaust outlets 116. The one or more purge gases P2 are exhausted through the one or more outlet openings 1025, through the same gaps between the upper liner 1020 and the lower liner 311, and through the same one or more exhaust outlets 116 as the one or more process gases P1. The present disclosure contemplates that that one or more purge gases P2 can be separately exhausted through one or more second gas exhaust outlets that are separate from the one or more exhaust outlets 116.

The present disclosure also contemplates that one or more purge gases can be supplied to the purge volume 138 (through the plurality of purge gas inlets 164) during the deposition operation, and exhausted from the purge volume 138.

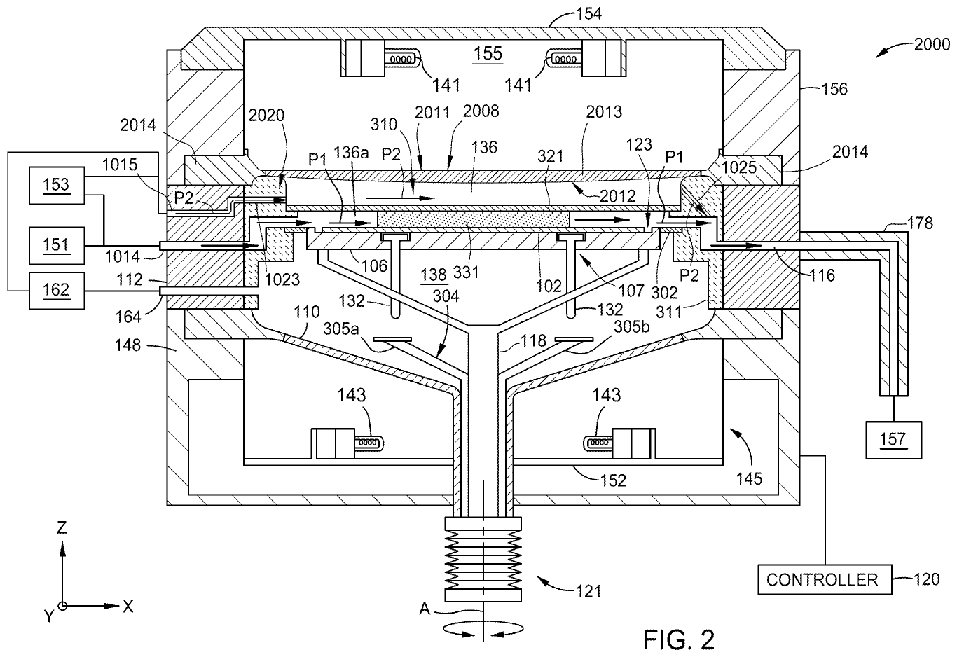

FIG. 2 is a partial schematic side cross-sectional view of a processing chamber 2000, according to one or more embodiments. The processing chamber 2000 is similar to the processing chamber 1000 shown in FIG. 1, and includes one or more of the aspects, features, components, properties, and/or operations thereof. The processing chamber 2000 is shown in a processing condition in FIG. 2.

The processing chamber 2000 includes a window 2008 that at least partially defines the processing volume 136. The window 2008 includes a first face 2011 that is concave or flat (in the embodiment shown in FIG. 2, the first face 2011 is flat). The window 2008 includes a second face 2012 that is convex. The second face 2012 faces the substrate support 106.

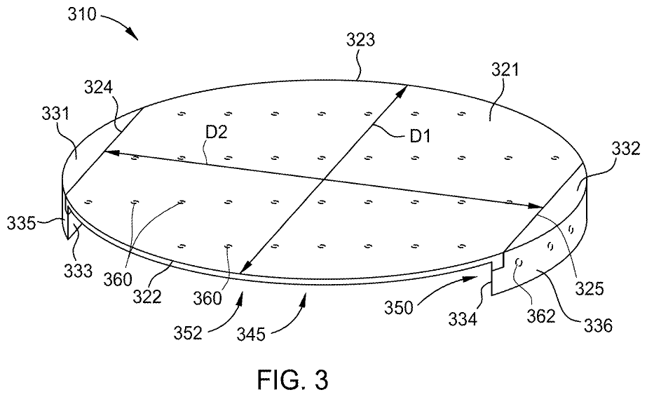

The processing chamber 2000 includes a liner 2020. The liner 2020 is similar to the upper liner 1020 shown in FIG. 1, and includes one or more of the aspects, features, components, properties, and/or operations thereof. The processing chamber 2000 incudes a process kit 310 (shown in FIG. 3), which includes a first block 331, a second block 332 (shown in FIG. 3), and an isolation plate 321. The isolation plate 321 and the blocks 331, 332 can function as a flow guide for the processing volume 136. The blocks 331, 332 are disposed below an isolation plate 321 and above the substrate support 106. In one or more embodiments, the blocks 331, 332 are parallel to each other. The blocks 331, 332 assist with flow of process gas P1 over the substrate 102 to facilitate improving deposition uniformity. In one or more embodiments, the isolation plate 321 and/or the blocks 331, 332 are supported by and/or coupled to the upper liner 1020 and/or the pre-heat ring 302. In one or more embodiments, the isolation plate 321 and/or the blocks 331, 332 rest on the upper liner 1020 and/or the pre-heat ring 302. In one or more embodiments the plate 321 has a thickness that is 20 mm or less, such as within a range of 10 mm to 20 mm.

The window 2008 includes an inner section 2013 and an outer section 2014. The first face 2011 and the second face 2012 are at least part of the inner section 2013. In one or more embodiments, the inner section 2013 is transparent and the outer section 2014 is opaque. The outer section 2014 is received at least partially in one or more sidewalls (such as in the flow module 112 and/or the upper body 156) of the processing chamber 2000. The blocks 331, 332 can be used in relation to the process kit 1010 shown in FIG. 1.

FIG. 3 is a schematic partial perspective view of the process kit 310, according to one or more embodiments. The process kit 310 includes the isolation plate 321, the first block 331, and the second block 332. The first block 331 and the second block 332 are disposed opposite one another and at least partially define an inlet 352 therebetween that receives gas(es) from the one or more inlet openings 114. In one or more embodiments, the first block 331 and the second block 332 are flow guide blocks. The process kit 310 has a circular shape, and other geometric configurations (such as a rectangular shape) are contemplated.

The isolation plate 321 includes a first side 322 and a second side 323 opposing the first side 322 along a first direction D1. Each of the first side 322 and the second side 323 is arcuate. In one or more embodiments, the direction D1 is parallel to the direction of gas flow in the process chambers 1000, 2000 of FIGS. 1 and 2 in order to guide process gas P1 within the rectangular flow opening 350 defined between a planar inner face 333 of the first block 331 and a planar inner face 334 of the second block 332.

In one or more embodiments, the first block 331 extends outwardly from and couples to a third side 324 of the isolation plate 321, and the second block 332 extends outwardly from and couples to a fourth side 325 of the isolation plate 321. The third side 324 is opposite the fourth side 325 along a direction D2, which is perpendicular to direction D1. The third side 324 and the fourth side 325 are linear, as are surfaces of the first block 331 and the second block 332 which mate with the third side 324 and the fourth side 325 of the isolation plate 321.

It is contemplated that the first block 331 and the second block 332 may be omitted from the process kit 310 (as shown in FIG. 1). The isolation plate 321 can be supported by the upper liner 1020 and/or the isolation plate 321 may be secured in the interior of the processing chamber via another attachment mechanism. In one or more embodiments the first block 331 and second block 332 are coupled to a curved section of the upper liner 1020. In one or more embodiments, the isolation plate 321 can be omitted and the blocks 331, 332 can be used.

The first block 331 and the second block 332 include one or more opaque outer surfaces defined at least partially by an opaque material. In one or more embodiments, all outer surfaces of the first block 331 and the second block 332 are opaque. In one or more embodiments, at least the inner face 333, 334 and/or an outer face 335, 336 of the respective block 331, 332 is opaque (for example opaque to infrared energy). The outer faces 335, 336 can be planar or curved (as shown in FIG. 3). In one or more embodiments, the isolation plate 321 is formed of a transparent material (such as transparent quartz).

In one or more embodiments, the first block 331 and the second block 332 include of graphite coated with an opaque material. A thickness of the opaque material is at least 50 microns, such as at least 100 microns, such as at least 0.5 mm, such as at least 1.0 mm, such as at least 1.5 mm, such as at least 2.0 mm, such as at least 2.5 mm, such as at least 3.0 mm, such as at least 3.5 mm, such as at least 4.0 mm, such as at least 4.5 mm, such as at least 5.0 mm. In one or more embodiments, the thickness of the opaque material is within a range of about 30 microns to about 200 microns. The opaque material has an average surface roughness (Ra) that is at least 10 micro-inches, such as at least 15 micro-inches, such as at least 20 micro-inches, such as at least 50 micro-inches, such as at least 75 micro-inches, such as at least 100 micro-inches, such as at least 125 micro-inches, such as at least 150 micro-inches, such as at least 175 micro-inches, such as at least 200 micro-inches, such as at least 225 micro-inches, such as at least 250 micro-inches In one or more embodiments, the average surface roughness of the opaque material is within a range of about 0.5 microns to about 50 microns. In one or more embodiments, the opaque material has an atomic structure that is non-crystalline (e.g., amorphous or polymorphous). In one or more embodiments the opaque material includes silicon carbide (SiC). The present disclosure contemplates that other materials, for example opaque quartz (such as white quartz, grey quartz, clear quartz impregnated with Si particles or SiC particles, and/or black quartz) can be used for the opaque material. In one or more embodiments, the opaque material has an atomic structure of 3C (e.g., 3C-SiC). In one or more embodiments, the atomic structure is 4H (e.g., 4H-SiC), or 6H (e.g., 6H-SiC). In one or more embodiments the first block 331 and the second block 332 are formed of an opaque material. In one or more embodiments the first block 331 and the second block 332 are formed of silicon carbide (SiC).

It is contemplated that the size of the parallel blocks may be varied to increase or decrease the lower portion 136a of the processing volume 136. It is also contemplated that the first and second blocks 331, 332 may include actuating supports configured to mechanically move the isolation plate 321 up and down. In one or more embodiments the first block 331 and the second block 332 have a rectangular shape. In one or more embodiments, the first block 331 and the second block 332 have a semi-circular shape. The first block 331 and the second block 332 are supported on the pre-heat ring 302 (FIG. 1).

During processing, one or more process gases (such as process gas P1 of FIGS. 1 and 2) flow through the rectangular flow opening 350 when flowing through the lower portion 136a and over the substrate 102. The rectangular flow opening 350 facilitates adjustability of process gases (such as deposition gases and/or cleaning gases) and/or purge gases (such as adjustability pressure and flow rate), to facilitate process uniformity and deposition uniformity while providing a path for cleaning gases to the upper portion 136b. As an example, the rectangular flow opening 350 facilitates using high pressures and low flow rates for the process gases and the cleaning gases. The rectangular flow opening 350 also facilitates mitigation of the effects that rotation of the substrate 102 has on process uniformity and film thickness uniformity during a deposition operation. As an example, the rectangular flow opening mitigates or removes the effects of gas vortex. The blocks 331, 332 are disposed on opposing sides of the rectangular flow opening 350.

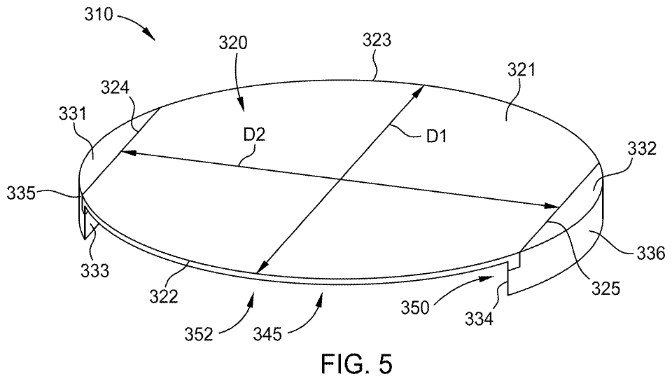

In FIG. 3, the isolation plate 321 includes a plurality of perforations 360 formed therethrough. It is contemplated that the plurality of perforations 360 can be omitted (as shown in FIG. 5). The perforations 360 are sized, spaced (e.g., for hole density) and angled to allow gas (e.g., purge gas P2 of FIGS. 1 and 2) to flow from a top side thereof to a bottom side thereof during processing. The perforations 360 can be circular or another shape. During processing, purge gas P2 flows through the perforations of the isolation plate 321 from the upper portion 136b to the lower portion 136a (see FIGS. 1 and 2). The purge gas P2 can form a relatively thin gas curtain along the bottom surface (e.g., the surface facing substrate 102) of the isolation plate. The gas curtain reduces material deposition on the isolation plate 321, extending time between cleaning operations. In addition, the gas curtain allows a substrate to be positioned closed to the isolation plate 321 during processing, thus reducing the processing volume and the amount of processing gas utilized.

The blocks 331, 332 also include a plurality of perforations 362. It is contemplated that the plurality of perforations 362 can be omitted (as shown FIG. 5). The perforations 362 can be circular or another shape. The perforations 362 are operatively and fluidly coupled to a gas source for supplying a gas. For example, the perforations 362 may receive a purge gas from the purge gas source 162. The gas provided through the perforations 362 in the direction D2 facilitates improved gas flow along the direction D1. In one or more embodiments, the gas provided through perforations 362 concentrates gas flow of a process gas P1 (see FIGS. 1 and 2) flowing in a direction D1, thus facilitating improving deposition uniformity on a substrate. In one or more embodiments, the gas provided through perforations 362 facilitates flowing process gas P1 nearer to the substrate 102 (see FIGS. 1 and 2), reducing or eliminating diversive flow of the process gas P1, and reducing or eliminating flowing of the process gas P1 up into the upper portion 136b.

Although, in FIG. 3, both the isolation plate 321 and the blocks 331, 332 have perforations 360, 362, it is contemplated that perforations 360, 362 can utilized on only the isolation plate, only the first block 331, only the second parallel block, 332, or any combination thereof. As shown in FIG. 5 both the perforations 360 and the perforations 362 can be omitted. Additionally, it is to be noted that while perforations 362 are shown in the second block 332 in FIG. 3 for clarity, perforations 362 are also formed in the first block 331.

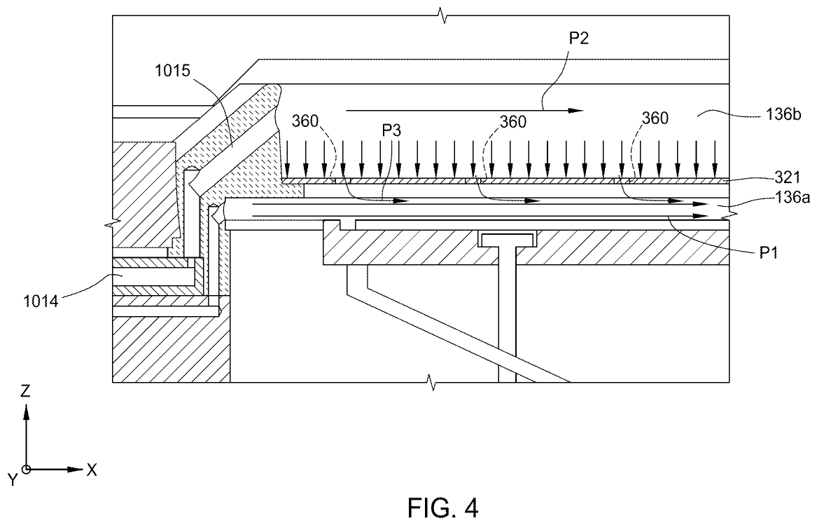

FIG. 4 is a partial schematic side cross-sectional view of an isolation plate 321 within a processing chamber 1000, 2000, according to one or more embodiments. The one or more inlet openings 1014 allow flow of the one or more process gases P1 into the process chamber. The one or more second inlet openings 1015 allow flow of the purge gas P2 into the upper portion 136b of the process chamber. The perforations (shown in FIG. 3) in the isolation plate 321 allow for at least a portion of the purge gas P2 to flow from the upper portion 136b of the process chamber into the lower portion 136a. The flow of the process gas P1 directs the flow of the purge gas P2 towards an exhaust of the process chamber as a flow P3. The flow P3 travels along a lower surface of the isolation plate 321, reducing or preventing deposition of material from the process gas P1 onto the isolation plate 321. The flowrate of the flow P3 is determined in part by the flow rate of the purge gas P2 and the location, number, size, and shape of the perforations 360 in the isolation plate 321. The present disclosure contemplates that the purge gas P2 can be replaced with a cleaning gas (e.g., hydrochloric acid).

Without being limited to theory, the flow P3 can reduce the potential for deposition on the isolation plate 321 by forming a gas curtain and or diluting the process gas P1 concentration adjacent the isolation plate 321. The flow P3 also pushes the process gas flow P1 towards the substrate surface, increasing the gas speed delta between the peak speed and the speed at the substrate surface.

FIG. 5 is a schematic partial perspective view of a process kit 510, according to one or more embodiments. The process kit 510 is similar to the process kit 310 shown in FIG. 3, and includes one or more of the aspects, features, components, properties, and/or operations thereof.

The process kit 510 omits the plurality of perforations 360, 362 shown in FIG. 3. During processing, one or more process gases (such as process gas P1 of FIGS. 1 and 2) flow through the rectangular flow opening 350 when flowing through the lower portion 136a and over the substrate 102. The rectangular flow opening 350 facilitates adjustability of process gases, purge gases, and/or cleaning gases (such as pressure and flow rate), to facilitate process uniformity and deposition uniformity while providing a path for cleaning gases to the upper portion 136b.

During processing, purge gas P2 flows over the isolation plate 321 in the upper portion 136b (see FIGS. 1 and 2). The isolation plate 321 separates the process gas P1 and the purge gas P2. The flowing of the one or more purge gases P2 through the upper portion 136b facilitates reducing or preventing flow of the one or more process gases P1 into the upper portion 136b that would contaminate the upper portion 136b.

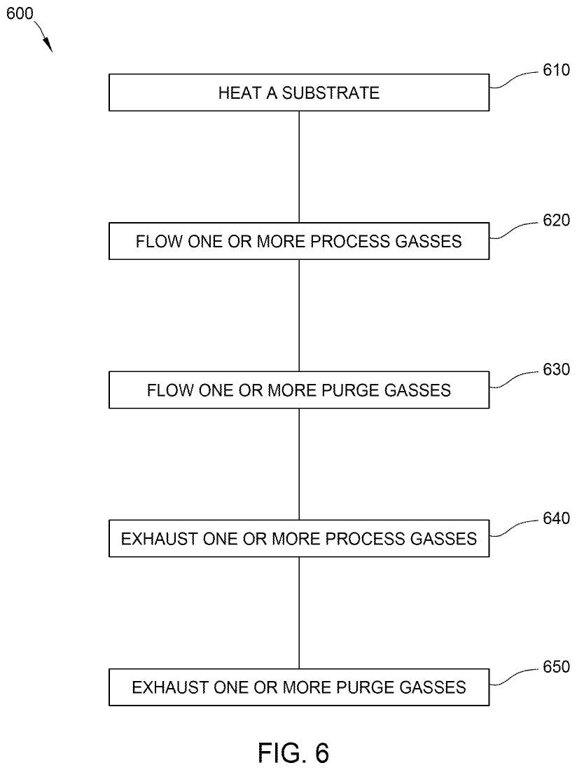

FIG. 6 is a schematic block diagram view of a method 600 of processing substrates 102, according to one or more embodiments.

Operation 610 includes heating a substrate positioned on a substrate support. In one more embodiments, the substrate is heated using heat sources and the substrate support is a pedestal, such as a susceptor which absorbs radiation from the heat sources and transfers thermal energy to the substrate. In one or more embodiments, the substrate support includes one or more ring segments. In one or more embodiments the blocks 331, 332 described above are heated. In one or more embodiments, the substrate is heated to a temperature within a range of 650 degrees Celsius to 700 degrees Celsius.

Operation 620 includes flowing one or more process gases over the substrate to form one or more layers on the substrate. The flowing of the one or more process gases over the substrate includes guiding the one or more process gases through a rectangular flow opening of a flow guide insert. The rectangular flow opening can be defined at least partially, for example, by the blocks 331, 332 and the isolation plate 321 described above. In one or more embodiments, the one or more process gases are supplied at a pressure that is 300 Torr or greater, such as within a range of 300 Torr to 600 Torr, or greater. In one or more embodiments, the one or more process gases are supplied at a flow rate that is less than 5,000 standard cubic centimeters per minute (SCCM). In one or more embodiments, the substrate is rotated at a rotation speed that is less than 20 rotations-per-minute (RPM) during the flowing of the one or more process gases over the substrate. In one or more embodiments, the rotation speed is about 16 RPM. The one or more purge gases can flow into the processing chamber before, during, and/or after one or more of operation 610, operation 630, operation 640, and/or operation 650.

Operation 630 includes flowing one or more purge gases into the processing chamber. The one or more purge gases can flow into the processing chamber before, during, and/or after one or more of operation 610, operation 620, operation 640, and/or operation 650. The one or more purge gases can flow over the isolation plate described above. The one or more purge gases can flow from perforations (if used) in the isolation plate or perforations (if used) in the blocks, as described above. In one or more embodiments, operation 630 includes simultaneous flow of purge gas from the isolation plate and the parallel blocks for the entirety of operation 630. In one or more embodiments, operation 630 includes introducing purge gas into the lower portion of the processing area only from the isolation plate or the blocks. In one or more embodiments, operation 630 includes flow of purge gas from the isolation plate and the blocks for portions of operation 630.

In one or more embodiments, the method 600 includes lifting and/or lowering the isolation plate 321 by moving the blocks 331, 332 using the substrate support 106. In one or more embodiments, the method 600 includes lifting and/or lowering the isolation plate 321 relative to the blocks 331, 332 by moving the plurality of lift pins 132 disposed in the substrate support 106. The blocks 331, 332 can support the isolation plate 321.

While flowing the one or more process gases in operation 620 and the one or more purge gases in operation 630, the one or more process gases are thermally decomposed to form an epitaxial layer on an upper surface of a substrate.

Operation 640 includes exhausting the one or more process gases. Operation 640 may occur before, during, and/or after one or more of operation 620, operation 630, and/or operation 650.

Operation 650 includes exhausting the one or more purge gases. Operation 650 may occur before, during, and/or after one or more of operation 610, operation 620, operation 630, and/or operation 640. Operation 650 can occur simultaneously with operation 640.

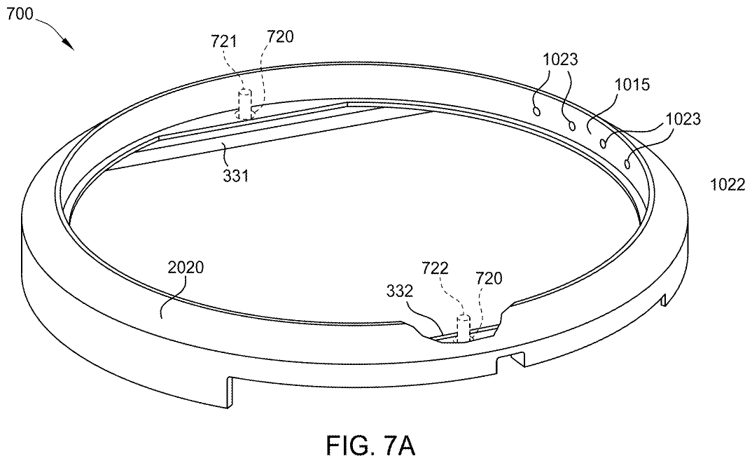

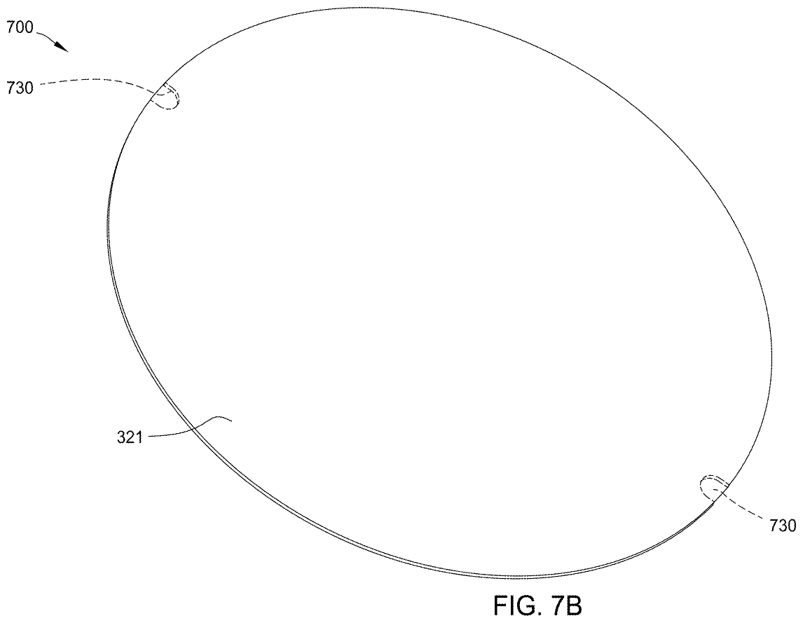

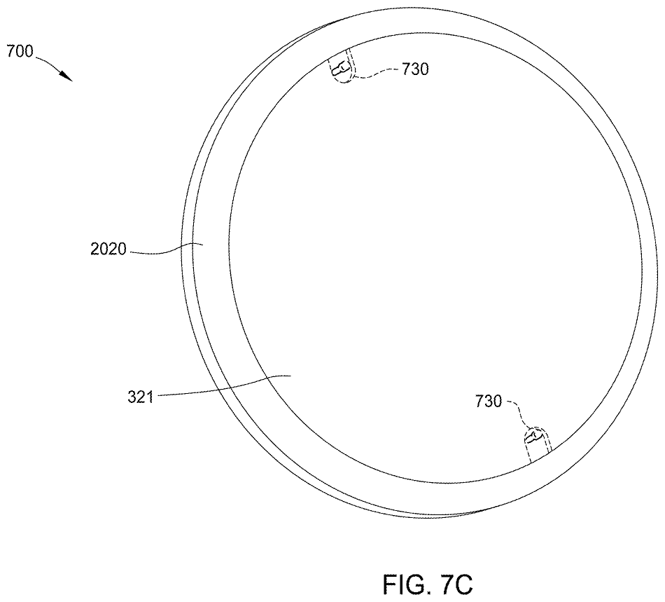

FIGS. 7A-7C are schematic partial perspective views of elements of a process kit 700, according to one or more embodiments.

FIG. 7A is a schematic partial perspective view of the liner 2020 and blocks 331, 332 of the process kit 700, according to one or more embodiments. The blocks 331, 332 are coupled to the liner 2020. In one or more embodiments, the blocks 331, 332 and the liner 2020 are manufactured together as a single integral part of the processing chamber 2000 such that the blocks 331, 332 and the liner 2020 are part of the same opaque body. In one or more embodiments, the blocks 331, 332 are manufactured as separate bodies from the liner 2020, and the blocks 331, 332 are fused to the liner 2020 in a fusing operation. In one or more embodiments, the blocks 331, 332 are welded to the liner 2020.

As shown in FIG. 7A, in one or more embodiments, the blocks 331, 332 includes optional slots 720. It is contemplated that the slots 720 may be omitted from the blocks 331, 332. The blocks 331, 332 respectively include one or more alignment extensions 721, 722 extending relative to the respective block 331, 332. The alignment extensions 721, 722 can include, for example, columns (such as cylindrical rods and/or rectangular rods). The one or more alignment extensions 721, 722 can be omitted.

FIG. 7B is a schematic partial perspective view of the isolation plate 321 of the process kit 700, according to one or more embodiments. In one or more embodiments, the isolation plate 321 includes notches 730. It is contemplated that the notches 730 may be omitted from the isolation plate 321. In one or more embodiments, the notches 730 of the isolation plate 321 and the slots 720 of the blocks 331, 332 are used to position the isolation plate 321 on the blocks 331, 332 and one or more inner ledges 1022 of the liner 2020. For example, transfer equipment (such as heads of lift pins) can extend through the notches 730 and into slots 720 when the isolation plate 321 is lowered onto the upper liner 1020. The lift pins can be part of the alignment extensions, and the alignment extensions 721, 722 can be movable relative to the blocks 331, 332. The alignment extensions 721, 722 can be coupled to the blocks 331, 332, and the alignment extensions 721 722 can extend through the notches 730 to align the isolation plate 321 relative to the blocks 331, 332.

FIG. 7C is schematic partial perspective view of the isolation plate 321 and the liner 2020 of the process kit 700, according to one or more embodiments. In one or more embodiments, the notches 730 and/or the alignment extensions 721, 722 vertically align with the slots 720 when the isolation plate 321 is positioned on the blocks 331, 332 and/or the one or more inner ledges 1022, and/or when the isolation plate 321 is fused to the blocks 331, 332 and/or the one or more inner ledges 1022. In one or more embodiments, the isolation plate 321 is fused to the blocks 331, 332 and/or the one or more inner ledges 1022. In one or more embodiments, the blocks 331, 332 and/or the one or more inner ledges 1022 are welded to the isolation plate 321. The liner 2020 can be formed of the same material as the blocks 331, 332 and/or the isolation plate 321.

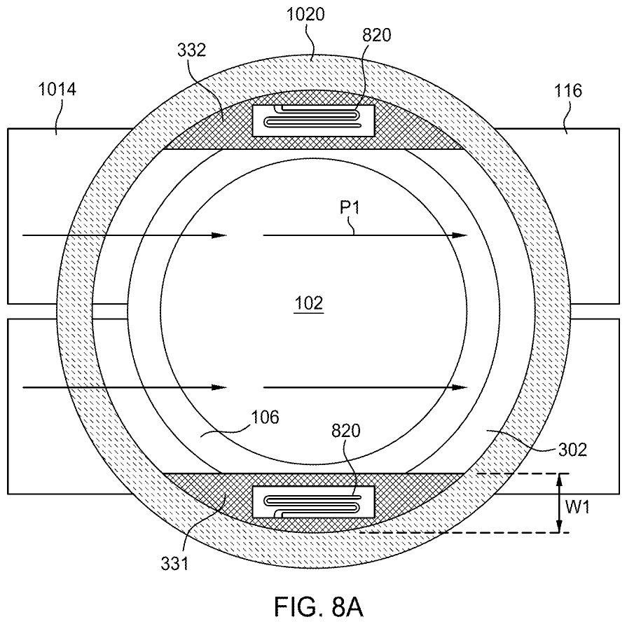

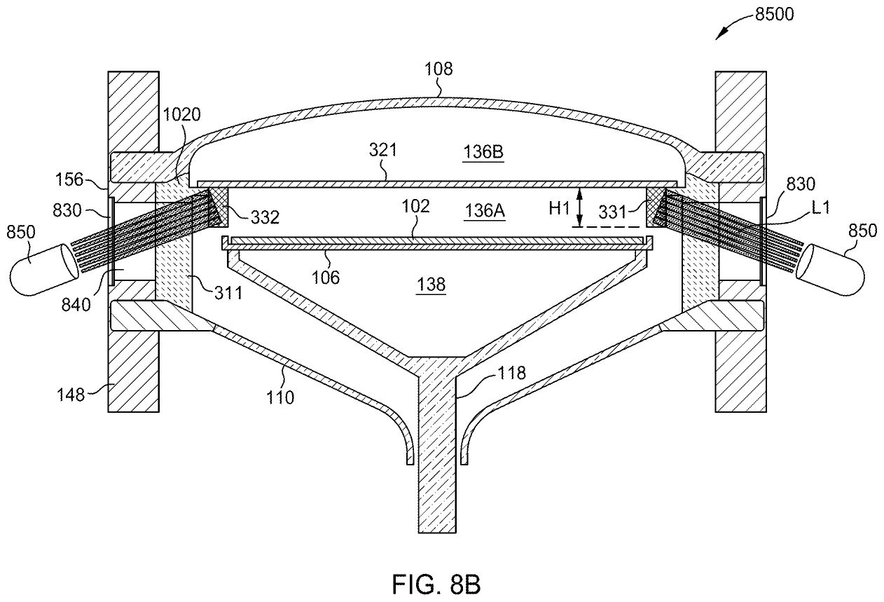

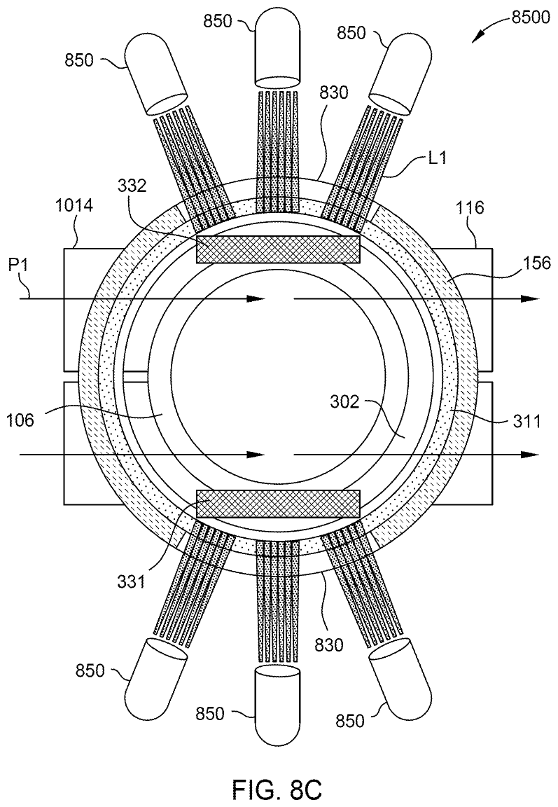

FIG. 8A is schematic cross-sectional top view of a processing chamber 8000, according to one or more embodiments. The processing chamber 8000 is similar to the processing chamber 1000 shown in FIG. 1, and processing chamber 2000 shown in FIG. 2, and includes one or more of the aspects, features, components, properties, and/or operations thereof. The isolation plate 321, the lid 154, the upper window 108, and other components are not shown for visual clarity purposes.

The processing chamber includes the first block 331 and the second block 332 shown in FIG. 3 and FIG. 5. In the implementation shown in FIG. 5, the first block 331 and the second block include one or more embedded heating elements 820. In one or more embodiments, the one or more embedded heating elements 820 function as resistive heaters for the first block 331 and the second block 332. During a deposition process and/or a cleaning process an electric current runs through the one or more embedded heating elements 820. The electric current heats the respective block 331, 332. The one or more embedded heating elements 820 heat the first block 331 and the second block 332 during the deposition process and/or the cleaning process.

The heated first block 331 and second block 332 help activate the process gas (such as P1) during the deposition process and/or the cleaning process. The activation of the blocks 331, 332 can be used in addition to the heating of the pre-heat ring 302. The activation of the blocks 331, 332 can facilitate reduced or eliminated edge roll-off of processing on the substrate 102. The activation can mitigate effects arising from temperature loss along areas of the substrate support 106 and/or the pre-heat ring 302. In one or more embodiments, the embedded heaters include electrical wires formed of metallic alloys including but not limited to nickel (Ni) alloys, nickel-chrome (NiCr) alloys, iron-crome-aluminum (FeCrAl) alloys, copper-nickel (CuNi) alloys, molybdenum (Mo) alloys, and/or tungsten (W) alloys. In one or more embodiments, the embedded heaters include electrical wires formed of non-metalic materials such as carbon (C). In one or more embodiments, an electric current is run through the first block 331 and the second block 332 to generate a voltage across the respective block 331, 332, which can heat the respective block 331, 332. The embedded heaters can be embedded in the respective block 331, 332 itself, or in a piece of material disposed in the respective block 331, 332. As an example where the first block 331 and the second block 332 are formed of SiC, then the embedded heaters are embedded in the SiC of the blocks 331, 332, and an entirety of the first block 331 and the second block 332 may act as resistive heaters when a current is applied to the first block 331 and the second block 332. As another example where the first block 331 and the second block 332 are formed of graphite coated with SiC, the embedded heaters can be embedded in the graphite or in a piece of material (such as SiC or quartz) disposed in the graphite. In one or more embodiments, a width W1 of the respective blocks 331, 332 is within a range of about 10 mm to about 50 mm, such as about 15 mm.

FIG. 8B is schematic cross-sectional side view of a processing chamber 8500, according to one or more embodiments. The processing chamber 8500 is similar to the processing chamber 1000 shown in FIG. 1, processing chamber 2000 shown in FIG. 2, and processing chamber 8000 shown in in FIG. 8A, and includes one or more of the aspects, features, components, properties, and/or operations thereof. The lift pins 132, the lid 154, and other components are not shown, for visual clarity purposes. FIG. 8B shows processing chamber 8500 rotated by an angle (such as 90 degrees) from processing chamber 1000 shown in FIG. 1 and processing chamber 2000 shown in FIG. 2.

Processing chamber 8500 includes one or more transparent (quartz) windows 830 disposed inwardly or in one or more openings of one or more sidewalls of the chamber body. In one or more embodiments, the one or more quartz windows 830 are disposed between the upper body 156 and the lower body 148. A gap 840 is formed between the upper body 156 and the lower body 148. One or more heating elements 850 are disposed outside of the processing chamber 8500 aligned with the one or more quartz windows 830. It is contemplated that in one or more embodiments the heating elements 850 are laser sources. In one or more embodiments the heating elements 850 are light-emitting diodes (LED), laser sources, and/or infrared lamps. Other energy sources are contemplated.

During a deposition process, the one or more heating elements 850 emit light L1 (such as light beams). The light L1 are emitted through the one or more quartz windows 830 and the gap 840 to the lower liner 311. In one or more embodiments the lower liner 311 is formed of a transparent material such as clear quartz in order for the light L1 to be able to emit through the lower liner 311 to the first block 331 and the second block 332. As discussed above, the first block 331 and the second block 332 are at least partially formed of the opaque material, which absorbs the energy from the light L1. The energy from the one or more light beams L1 causes the first block 331 and the second block 332 to heat up. The heated first block 331 and second block 332 help activate the process gas during the deposition process. It is contemplated that the heating elements 850 and the light L1 may be used in conjunction with the embedded heating elements 820 shown in FIG. 8A. In one or more embodiments, a height H1 of the respective blocks 331, 332 is within a range of about 5 mm to about 20 mm, such as about 12 mm.

FIG. 8C is a schematic cross-sectional top view of the processing chamber 8500 shown in FIG. 8B, according to one or more embodiments. The isolation plate 321, the lid 154, the upper window 108, and other components are not shown, for visual clarity purposes.

FIG. 8C depicts the processing chamber 8500 with a plurality of (e.g., three) heating elements 850 used together to light L1 to the first block 331 and a plurality of (e.g., three) heating elements 850 used together to emit light L1 to the second block 332. The light L1 is emitted through one or more quartz windows 830. In one or more embodiments, the quartz window(s) 830 are disposed in opening(s) formed in the upper body 156 and/or lower body 148, so that the light L1 could be emitted from any direction. The light L1 emits through the one or more quartz windows 830 and through the lower liner 311. FIG. 8C depicts the lower liner 311 formed entirely from clear quartz. It is contemplated that in one or more embodiments the lower liner 311 is partially made from an opaque material and partially made from clear quartz. In one or more embodiments the lower liner includes a clear quartz widow similar to the quartz window 830 in the chamber body. Although a total of six heating elements 850 are shown in FIG. 8C, it should be understood that any number of heating elements 850 can be used, including 1 heating element, 2 heating elements, 4 heating elements, or 8 heating elements. The blocks 331, 332 are shown as rectangular in FIG. 8C. The one or more heating elements 850 are disposed radially outwardly of the first and second flow guide blocks 331, 332 and the one or more quartz windows 830.

The present disclosure contemplates that power supplied to the heating elements 820, 850 can be controlled independently of the heat sources 141, 143 (FIG. 1) that heat the substrate 102. The present disclosure contemplates that the blocks 331, 332 can be heated by absorbing light from the heat sources 141, 143 in addition to or in place of the light L1 from the heating elements 850.

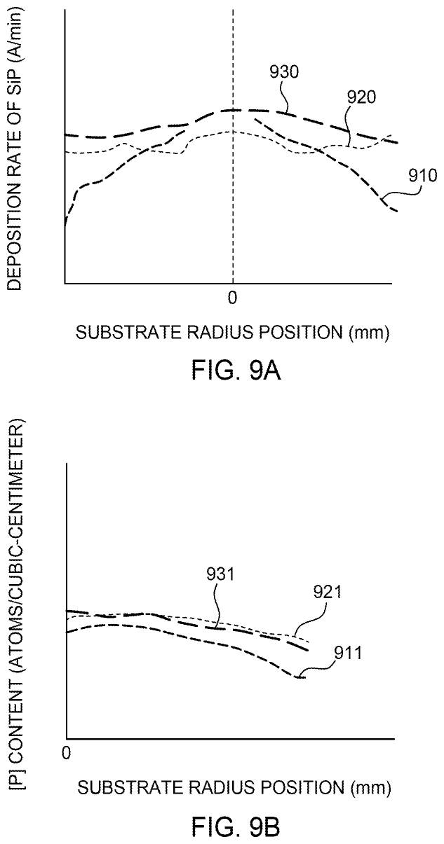

FIG. 9A is a graphical representation of the deposition rate on a substrate during an epitaxial deposition process using various implementations, according to one or more embodiments.

Line 910 represents the deposition rate on a substrate without the use of blocks (such as blocks 331, 332). The deposition rate decreases on the outer portions of the radius of the substrate. Line 920 represents a deposition rate on a substrate using blocks. The deposition rate of line 920 is more uniform compared to line 910 (such as in a direction from a middle of the substrate toward an outer radius of the substrate). Line 930 represents a deposition rate on a substrate with blocks described herein (such as block 331, 332). The deposition rate of line 930 is higher than the deposition rate of line 920, and exhibits a more uniform deposition compared to line 910 (such as in a direction from a middle of the substrate toward an outer radius of the substrate).

FIG. 9B is a graphical representation of the phosphorous content on a substrate during an epitaxial deposition process using various implementations, according to one or more embodiments.

Line 911 shows a phosphorous content on a substrate without the use of blocks (such as blocks 331, 332). Line 921 represents the phosphorus content on a substrate using blocks. Line 931 represents a phosphorus content on a substrate with blocks described herein (such as block 331, 332). Both line 921 and line 931 show a higher phosphorus content than line 911, and a higher phosphorus content uniformity (such as in a direction from a middle of the substrate and towards the outer radius of the substrate).

Benefits of the present disclosure include enhanced gas activation (such as by enhanced pre-heating); reduced diversive flow of process gases; gas savings; heating savings; enhanced deposition thicknesses; enhanced processing uniformities; and increased throughput and efficiency.

It is contemplated that one or more aspects disclosed herein may be combined. As an example, one or more aspects, features, components, operations and/or properties of the processing chamber 1000, the processing chamber 2000, the process kit 310, the process kit 510, the method 600, the process kit 700, the processing chamber 8000, and/or the processing chamber 8500 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber applicable for use in semiconductor manufacturing, comprising:
a chamber body at least partially defining an internal volume;
one or more heat sources operable to heat the internal volume;
a substrate support disposed in the internal volume;
one or more inlet openings configured to direct a gas across a gas flow path over the substrate support and to one or more exhaust outlets; and
a process kit disposed in the internal volume, the process kit comprising:
a first flow guide block; and
a second flow guide block disposed opposite the first flow guide block with respect to the gas flow path, the first flow guide block and the second flow guide block respectively comprising one or more opaque outer surfaces.

2. The processing chamber of claim 1, wherein the process kit further comprises:
a plate disposed in the internal volume and at least partially fluidly isolating a processing section of the internal volume from an outward section of the internal volume, wherein the first flow guide block supports least a first portion of the plate and the second flow guide block supports at least a second portion of the plate.

3. The processing chamber of claim 1, wherein the first flow guide block and the second flow guide block are supported on a pre-heat ring disposed outwardly of the substrate support.

4. The processing chamber of claim 2, wherein the first flow guide block and the second flow guide block are coupled to a curved section of a liner disposed outwardly of, and the first flow guide block and the second flow guide block are fused to or integrally formed with the curved section of the liner.

5. The processing chamber of claim 1, wherein the first flow guide block and the second flow guide block define a rectangular flow opening between a first planar inner face of the first flow guide block and a second planar inner face of the second flow guide block.

6. The processing chamber of claim 4, wherein the first flow guide block and the second flow guide block are movable relative to the liner.

7. The processing chamber of claim 1, further comprising one or more heating elements operable to heat the first flow guide block and the second flow guide block.

8. The processing chamber of claim 7, further comprising quartz material disposed outwardly of the first flow guide block, wherein the one or more heating elements are disposed outside of the quartz material.

9. The processing chamber of claim 8, wherein the one or more heating elements are disposed radially outwardly of the first and second flow guide blocks and the quartz material, and the one or more heating elements respectively comprise one or more of a laser source, a light-emitting diode (LED), or a lamp.

10. The processing chamber of claim 7, wherein the one or more heating elements are disposed at least partially in the first flow guide block and the second flow guide block.

11. The processing chamber of claim 10, wherein the one or more heating elements include one or more electrical wires that include one or more of carbon or metal.

12. A process kit applicable for use in semiconductor manufacturing comprising:
a plate;
a first block operable to support at least a first portion of the plate; and
a second block operable to support at least a second portion of the plate, the first block and the second block respectively comprising one or more opaque outer surfaces.

13. The process kit of claim 12, wherein the first block and the second block are sized and shaped to define a rectangular flow opening defined between a first planar inner face of the first block and a second planar inner face of the second block.

14. The process kit of claim 12, wherein the first block and the second block respectively are formed of graphite coated with an opaque material.

15. The process kit of claim 14, wherein a thickness of the opaque material is within a range of about 30 microns to about 200 microns.

16. The process kit of claim 12, wherein the first block and the second block respectively is formed of an opaque material.

17. The process kit of claim 16, wherein the opaque material includes silicon carbide (SiC).

18. The process kit of claim 12, wherein at least one of the one or more opaque outer surfaces have an average surface roughness within a range of about 0.5 microns to about 50 microns.

19. A method of processing substrates, comprising:
heating a substrate positioned on a substrate support; and
flowing one or more process gases over the substrate to form one or more layers on the substrate, the flowing of the one or more process gases over the substrate comprising flowing the one or more process gases over a pair of blocks having opaque surfaces defining a rectangular flow opening.

20. The method of claim 19, further comprising heating the pair of blocks.
